(19) United States
(12) Patent Application Publication
(10) Pub. No.: US 2003/0232284 A1
(43) Pub. Date: Dec. 18, 2003

(54) Method of forming a system on chip

(76) Inventors: Chien-Hung Liu, Taipei City (TW); Shyi-Shuh Pan, Kao-Hsiung City (TW); Shou-Wei Huang, Chi-Lung City (TW); Ying-Tso Chen, Kao-Hsiung Hsien (TW); Erh-Kun Lai, Tai-Chung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,113

(22) Filed: Jun. 12, 2002

(51) Int. Cl. G03F 7/16; G03F 7/20; G03F 7/40; H01L 21/20; H01L 21/36; H01L 21/425; H01L 21/311; H01L 21/31; H01L 21/469

(52) U.S. Cl. 430/314; 430/316; 430/317; 430/319; 438/479; 438/514; 438/703; 438/763

(57) ABSTRACT

A method of forming a system on chip(SOC) comprising read only memory(ROM) and nitride read only memory(NROM) by utilizing nitride read only memory. The method is to form a plurality of field oxide layers on a surface of a substrate in order to define an active area of each device. An ONO dielectric layer is then formed on the surface of the substrate, thereafter performing a photolithography and ion implantation process to form a plurality of N-type bit lines and P-type pocket doping areas in the substrate inside the memory area. After that, an etching process is performed in order to remove regions of the ONO dielectric layer in the periphery area and regions of the ONO dielectric layer in the memory area, optionally. After that, a thermal oxidation process is utilized in order to form a buried drain oxide layer atop each bit line and a gate oxide layer on the surface of the active area in the periphery area, respectively. Then, a polysilicon layer is deposited on the surface of the substrate and a photolithography and etching process are utilized in order to simultaneously form a word line in the memory area and the gates of the periphery transistor in the periphery area. Finally, a ROM code process is performed to adjust the threshold voltage of the high threshold voltage(high Vth) device in the read only memory area.

### BACKGROUND OF THE INVENTION

1. Field of the Invention

The present invention provides a method of forming a system on chip (SOC),and more particularly, to a method of forming a system on chip that establishes read only memory (ROM) and non-volatile memory by utilizing nitride read only memory (NROM).

2. Description of the Prior Art

A read only memory (ROM) device is a semiconductor device for data storage. It has a plurality of memory cells and is applied in data storage and memory systems of computers widely today. Read only memory can be classified into mask ROM, programmable ROM (PROM), erasable programmable ROM (EPROM), electrically erasable programmable ROM (EEPROM), nitride read only memory (NROM), and flash ROM, according to the method used for data storage. Read only memory has a feature that once data or information is stored, the data or information will not disappear because of an interruption of power, therefore read only memory is also called non-volatile memory.

Nitride read only memory (NROM) is characterized as utilizing a silicon nitride isolation dielectric layer as a charge trapping medium. Since the silicon nitride layer is highly dense, hot electrons can tunnel into the silicon nitride layer and be trapped inside it through a tunneling oxide. This further forms an inhomogeneous density distribution that accelerates a rate of data reading and avoids leakage current. Flash ROM utilizes a floating gate composed of polysilicon or metal to store charges, therefore it has an extra gate aside from the control gate. NROM has the advantage of a simple manufacturing process that leads to low cost. Since flash ROM needs to be made with a floating gate-inter-dielectric layer-control gate structure, and the quality of materials in the three-layer structure is very important, it is necessary to use a suitable process, resulting in a more complex manufacturing process and higher cost.

In the modern electrical industry, read only memory and the non-volatile memory often need to exist in various products at the same time. In contrast to the two devices manufactured in a single chip, the two devices manufactured in two separate chips will occupy more room and also lift the cost. Therefore in U.S. Pat. No. 5,403,764, Yamamoto et al. proposes a method of implanting ROM code into the flash ROM device in the ROM region by utilizing an ion implantation process during a flash ROM manufacturing process, in other words, completing the “read” procedure, then completing the manufacturing process of flash ROM. So, read only memory can be established in some portion of the flash ROM chip.

Please refer to FIG. 1 to FIG. 5. FIG. 1 to FIG. 5 are schematic diagrams of a process for making a flash ROM chip 10 comprising read only memories 24, 26 in the read only memory area 18 according to the prior art. As shown in FIG. 1, the prior art method of forming a flash ROM chip 10 comprising read only memories 24, 26 in the read only memory area 18 is to provide a semiconductor wafer 11 comprising P type silicon base 12, then to utilize a thermal oxidation process at a temperature of about 1100° C. and using a process time of about 90 minutes to form a silicon dioxide (SiO₂) layer 14 with a thickness of several thousand angstroms(Å) on the surface of the silicon base 12 not covered by the oxidation-protective film(not shown), such as silicon nitride(Si₃N₄). After that the remaining silicon nitride layer(not shown) is removed and a very thin silicon oxide layer 16 is preserved in between the silicon dioxide layer 14 and the silicon dioxide layer 14, that is, in between each field oxide layer. In other words, local oxidation(LOCOS) is utilized to form an isolation between each transistor completed afterwards.

As shown in FIG. 2, an ion implantation process is then performed in the read only memory area 18 on the flash ROM chip 10. The ion implantation process utilizes an accelerating energy ranging from 40 to 50 keV, and a Boron ion dosage ranging from 1E12 to 3E12/cm² to form a first P+type doping area 22 with ion concentration ranging from 10¹⁶ to 10¹⁷/cm³. The objective of the ion implantation process is to adjust the threshold voltage (Vth) of the first read only memory(not shown) in the read only memory area 18 to a first specific value. The threshold voltage of the first read only memory (not shown) is adjusted to around 1V and stores a data “1”.

As shown in FIG. 3, a first photolithography process is then performed in order to form a first mask 31 out of the read only memory area 18 and the read only memory (not shown) with a second specific value as its threshold voltage. Thereafter, an ion implantation process is performed on the flash ROM chip 10. The ion implantation process utilizes an accelerating energy ranging from 40 to 50 keV, and a Boron ion dosage ranging from 5E12 to 1E13/cm² to form a second P+ type dopant area 32 with final ion concentration ranging from 10¹⁷ to 10¹⁸/cm³. The objective of the ion implantation process is to adjust the threshold voltage(Vth) of the second read only memory(not shown) in the read only memory area 18 to a second specific value. The threshold voltage of the second read only memory(not shown) is adjusted to around 7V and stores a data “0”.

As shown in FIG. 4, a first polysilicon layer 34, an interlayer isolation layer 36 composed of silicon nitride or silicon oxide and a second polysilicon layer 38 are then deposited on the flash ROM chip 10. After that, a second photolithography process is performed in order to form a double gate 39 of the first read only memory 24, the second read only memory 26 and the flash ROM 40. Although the gate structures of the first read only memory 24 and the second read only memory 26 are single layered in general, and the double gate 39 with the three layered structure is not required, all of the gates are completed with the same process steps in the prior art method in order to reduce process steps.

As shown in FIG. 5, a phosphorous ion implantation process is performed by utilizing a third mask (not shown) in order to form an N+ source 41 and an N+ drain 42 at either side of the double gate 39 of the first read only memory 24 and the second read only memory 26 to complete the manufacturing of the first read only memory 24 and the second read only memory 26. Finally another phosphorous ion implantation process is performed by utilizing a fourth mask (not shown) in order to form an N+ source 43 and an N+ drain 44 at either side of the double gate 39 of the flash ROM 40 to complete the manufacturing of the flash ROM 40. Therefore not only the read only memories 24, 26 on the flash ROM chip 10 are written with “0” or “1,” but the flash ROM 40 is also completed by just adding two process steps for threshold voltage adjustment in the standard flash ROM manufacturing process.

However, as the flash ROM chip in the prior art only comprises some read only memory, the objective of system on chip is not achieved. Moreover, the cost of flash ROM is more expensive, and therefore not suitable to the manufacturing of system on chip. Therefore it is very important to develop a system on chip that utilizes the device with a cheaper cost, and its manufacturing process, to simultaneously make the read only memory and the nitride read only memory on the same chip, and omit the electrical writing step for the general non-volatile memory after completion.

### SUMMARY OF THE INVENTION

It is therefore a primary objective of the present invention to provide a method of forming a system on chip (SOC), and more particularly, to a method of forming a system on chip that establishes read only memory (ROM) and non-volatile memory by utilizing nitride read only memory (NROM).

In a first preferred embodiment of the present invention, a system on chip is made on a surface of a semiconductor wafer and a nitride read only memory(NROM) manufacturing process is utilized to simultaneously make read only memory and nitride read only memory. The method according to the present invention starts by forming an ONO structure layer composed of bottom oxide layer-silicon nitride layer-top oxide layer on a surface of a substrate. A first ion implantation process is then performed by utilizing a first photoresist layer as a mask to form a plurality of N+ dopant areas in the substrate and to form bit lines in the memory area. Two angled ion implantation processes are performed in order to form a P− pocket doping area at either side of each bit line. A third dry etching process is performed on the surface of the substrate by utilizing a second photoresist layer in order to remove, optionally, regions in the ONO structure layer in the memory area, and the ONO structure layer all over a periphery area. A buried drain oxide layer is formed, atop the bit line, by utilizing thermal oxidation as an isolation of each silicon nitride layer and simultaneously forming a gate oxide layer on the silicon substrate in the periphery area. A polysilicon layer is deposited on the ONO structure layer and the buried drain oxide layer. A third photolithography process and a fourth dry etching process are performed in order to remove the polysilicon layer not covered by a third photoresist layer and simultaneously form a word line in the memory area and a gate of the periphery transistor in the periphery area. By utilizing a fourth photoresist layer and an ion implantation process for threshold voltage adjustment, the P-type dopant is implanted into the high threshold voltage(high Vth) device in the read only memory area to implant ROM code and adjust the threshold voltage of the high threshold voltage device in the read only memory area. Due to the existence of the high threshold voltage device and the low threshold voltage device in the read only area, they can be exercised as the read only memory. Therefore, the system on chip not only comprises the periphery transistor but also comprises the read only memory and the nitride read only memory.

It is an advantage of the present invention to utilize nitride read only memory and added ion implantation process to simultaneously make the read only memory and nitride read only memory on a system on chip. Therefore, not only the time and manpower exhausted by electrical writing, which leads to the unfeasibility of mass production, generally required after completing the non-volatile memory can be avoided, but also the low cost system on chip can be fabricated by keeping the process flow simple.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 to FIG. 5 are schematic diagrams of a process for making a flash ROM chip comprising read only memories in the read only memory area according to the prior art.

FIG. 6 to FIG. 12 are schematic diagrams of a process for forming a system on chip comprising read only memories in the read only memory area and a nitride read only memory in the nitride read only memory area by utilizing nitride read only memory according to the present invention.

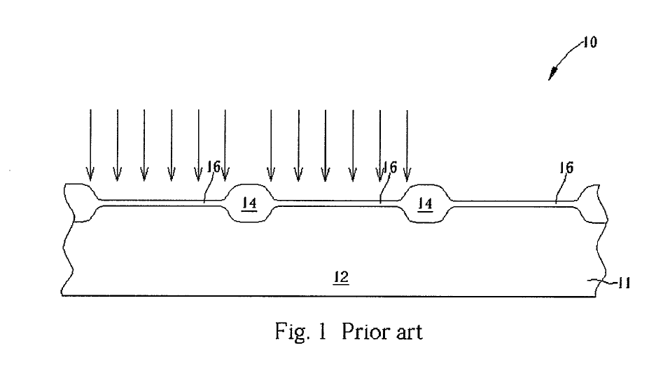

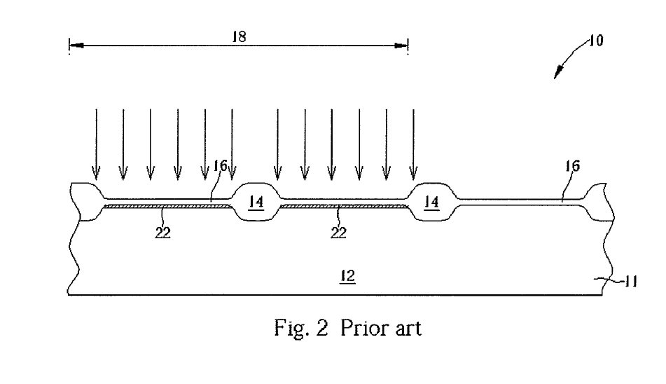

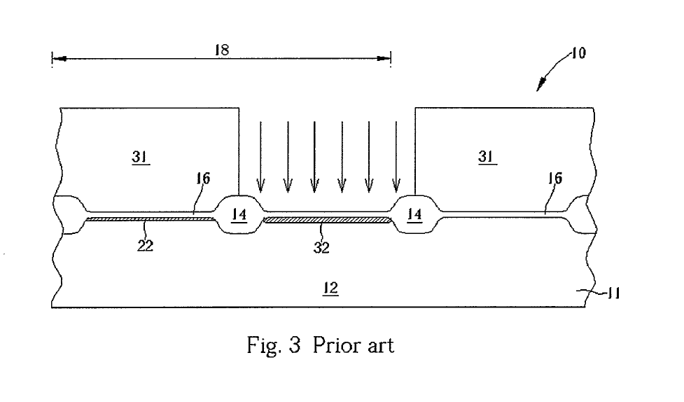

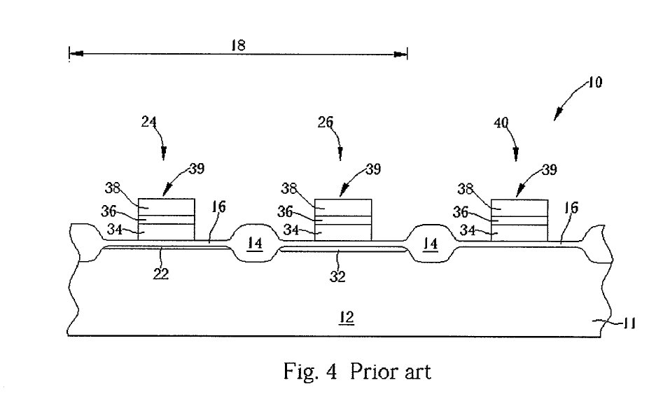

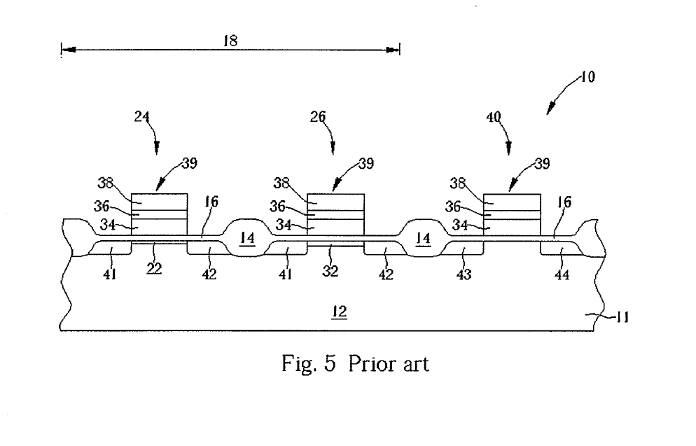

### DETAILED DESCRIPTION

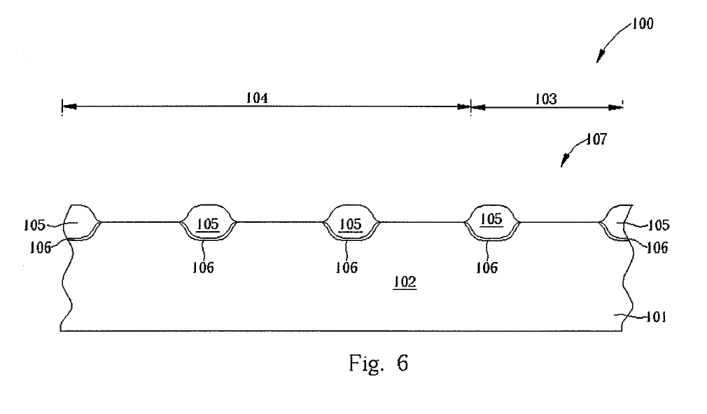

Please refer to FIG. 6 to FIG. 12. FIG. 6 to FIG. 12 are schematic diagrams of a process for forming a system on chip 100 comprising read only memories 142, 144 in the read only memory area 122 and nitride read only memory 146 in the nitride read only memory area 123 by utilizing nitride read only memory according to the present invention. As shown in FIG. 6, the method of forming the system on chip 100 according to the present invention is to provide a semiconductor wafer 101 comprising a P-type silicon base 102 first. The surface of the semiconductor wafer 101 comprises a periphery area 103 and a memory area 104. Then a standard process is performed to form a field oxide layer 105 on the semiconductor wafer 101 for use as isolation for each subsequently formed memory cell(not shown) and periphery transistor(not shown). Thereafter, some periphery process is performed, such as forming a channel stop 106 beneath the field oxide layer 105 by first utilizing a first ion implantation process, then removing all of the pad oxide layer(not shown). After that, a second ion implantation process is performed in order to perform the threshold voltage adjustment ion implantation into the active area 107 of the periphery transistor.

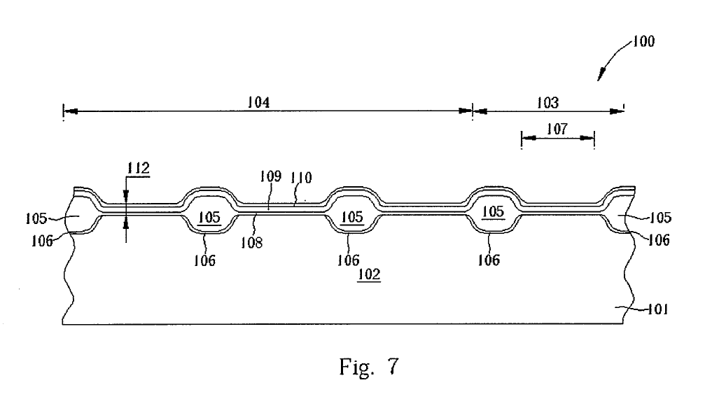

As shown in FIG. 7, a low temperature oxidation process with temperature ranging from 750° C.˜1000° C. is then utilized to form an oxide layer with a thickness ranging from 20˜150 angstroms(Å) on the surface of the silicon substrate 102 for use as a bottom oxide layer 108. Then, a low pressure vapor deposition(LPCVD) process is performed in order to form a silicon nitride layer 109 atop the bottom oxide layer 108 for using as a charge trapping layer. Finally, an annealing process is performed at 950° C. for 30 minutes to recover the structure of the silicon nitride layer 109, and a wet oxidation process is performed by inputting water vapor in order to form a silicon oxy-nitride layer with a thickness of 50˜200 angstroms atop the silicon nitride layer 109 for use as a top oxide layer 110. During a growth process of the top oxide layer 110, approximately 25˜100 angstroms of the silicon nitride layer 109 will be consumed. The bottom oxide layer 108, the silicon nitride layer 109, and the top oxide layer 110 formed atop the silicon base 102 are an ONO dielectric layer 112. Moreover, the pre-mentioned ion implantation process for adjusting the threshold voltage(Vt) can be performed at this point to avoid destruction of the lattice structure of the P-type silicon base 102.

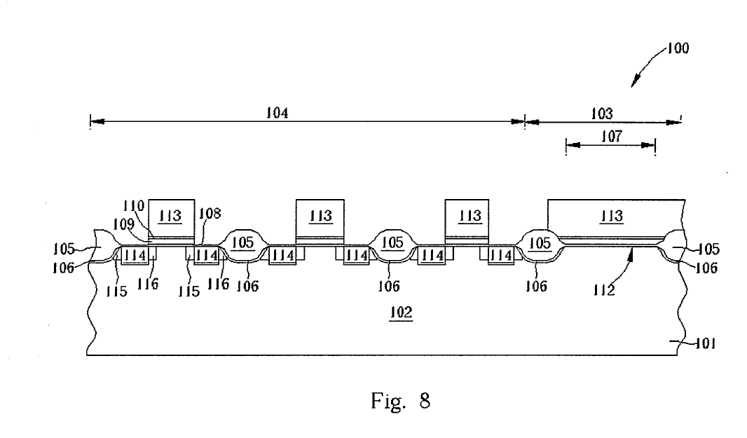

Then, as shown in FIG. 8, a first photoresist layer 113 is formed atop the ONO dielectric layer 112, and a first photolithography and etching process are performed in order to form a predefined pattern in the first photoresist layer 113 for defining the sites of bit lines. Thereafter, a dry etching process is performed in order to remove the top oxide layer 110 and the silicon nitride layer 109 not covered by the first photoresist layer 113, and etch the bottom oxide layer 108 not covered by the first photoresist layer 113 to a predetermined thickness by utilizing the first photoresist layer 113 as a mask. After that, an ion implantation process is performed with an arsenic dosage ranging from 2˜4 E15/cm² and an energy of approximately 50 keV in order to form a plurality of N+ doping area in the silicon base 102 for use as the bit lines 114 of memory cells. The bit lines 114 are also called a buried drain, each two neighboring doping areas defining a channel and the distance between the two neighboring doping areas being channel length.

After that, an angled ion implantation process is performed in order to form a P⁻-type pocket doping area 115 at one side of each bit line 114. Then, another angled ion implantation process is performed in order to form a P³¹-type pocket doping area 116 at another side of each bit line 114. These two angled ion implantation processes have about the same parameters except for an incident direction. The two angled ion implantation processes utilize BF²⁺ as a dopant, the dosage being approximately 1E13 to 1E15 ions/cm², the implantation energy being 20 to 150 KeV, the incident angle to silicon base 102 being approximately 20 to 45°. The two-angled ion implantation process can be performed before the ion implantation process for forming bit line 114. Under these process conditions, the highest concentration for the BF²⁺ dopants implanted into the silicon base 102 is located in the silicon base 102 underneath the channel with a depth of approximately 1000 angstroms, and the horizontal distance implanted underneath the channel ranges from approximately several hundred to 1000 angstroms. The objective for forming P⁻-type pocket doping areas 115 and 116 is to provide a high electric field area at one side of the channel. The high electric field area will enhance a hot carriers effect, improve a velocity when passing through the channel under programming. In other words, the electrons are accelerated in order to make more electrons acquire enough dynamic energy by way of collision or scattering effects to tunnel to the bottom oxide layer 108, penetrate into the silicon nitride layer 109, and further lift a writing efficiency.

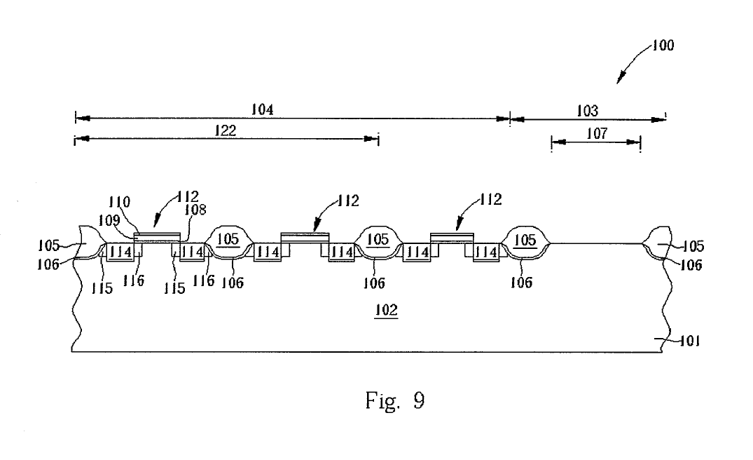

As shown in FIG. 9, an etching process is performed in order to remove the bottom oxide layer 108 not covered by the first photoresist layer 113. Then the first photoresist layer 113 is removed and a dry etching process is performed in order to remove the ONO dielectric layer 112 in a read only memory area 122 inside the memory area 104, optionally, and the ONO dielectric layer 112 in the periphery area 103. The objective of this process is to form a subsequent gate oxide layer(not shown) instead of the ONO dielectric layer 112, in order to form either a gate oxide layer or an ONO dielectric layer depending on device and product characteristics.

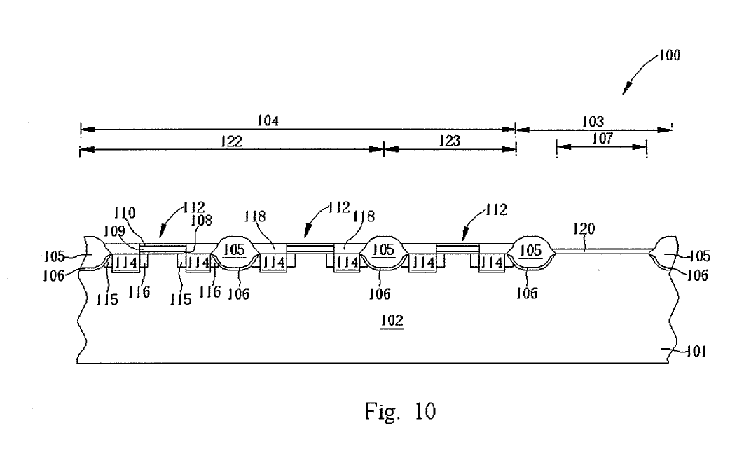

As shown in FIG. 10, a thermal oxidation process is performed in order to form a buried drain oxide layer 118 atop the bit lines 114, and activate the dopants in each bit line 114 by using thermal energy from the high temperature of the buried drain oxidation process. Furthermore, the thermal oxidation process will simultaneously form a gate oxide layer 120, with a thickness ranging from 100 to 250 angstroms, on the surface of the active area 107, in the periphery area 103 not covered by the ONO dielectric layer 112 on the surface of the semiconductor wafer 101. However, the gate oxide layer 120 will not be formed in the memory area 104 covered by the ONO dielectric layer 112 on the semiconductor wafer 101. Therefore, the present invention can preserve the ONO dielectric layer 112 or form the gate oxide layer 120 by simply utilizing the prescribed etching process and thermal oxidation in FIG. 9. This makes the ONO dielectric layer 112 exist in the whole memory area 104 or only exist in a nitride read only memory area 123 inside the memory area 104.

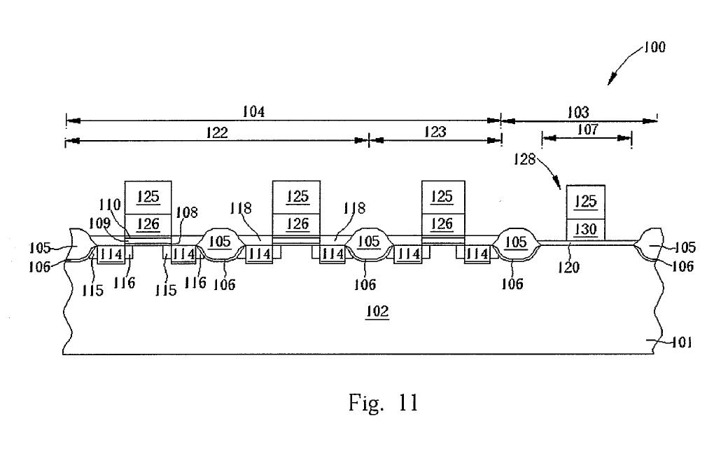

As shown in FIG. 11, after that, a polysilicon layer(not shown) or a polysilicon layer comprising a polysilicide layer is deposited on top on the surface of the ONO dielectric layer 112 and the buried drain oxide layer 118. Then, a second photolithography process is performed in order to form a second photoresist layer 125 on the surface of the polysilicon layer in order to define the sites of word lines 126 and the gate 130 of the periphery transistor 128. Thereafter, a dry etching process is performed to remove the polysilicon layer not covered by the second photoresist layer 125 in order to simultaneously form the word lines 126 and the gate 130 of the periphery transistors 128. Finally the second photoresist layer 125 is removed.

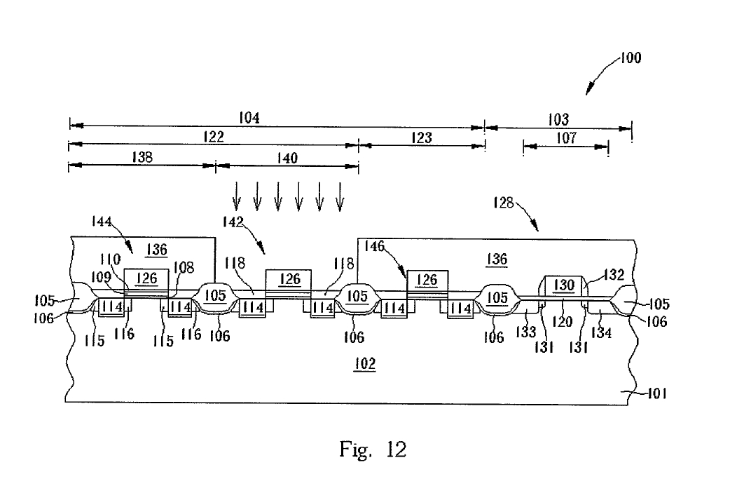

As shown in FIG. 12, after that, some process steps are performed in order to complete the unfinished process steps for the periphery transistors 128 in the periphery area 103 on the system on chip, continuously, such as a lightly doped drain (LDD) 131, a spacer 132 and source/drain(S/D) 133,134. Then, a third photoresist layer 136 is utilized to cover a low threshold voltage(low Vth) area 138 in the read only memory area 122, the whole periphery area 103, and the nitride read only memory area 123, and another threshold voltage adjustment ion implantation process is performed in order to implant P-type dopants into a high threshold voltage(high Vth) area 140 inside the read only memory area 122. This process step is also called the ROM code implantation process, and is used to adjust the threshold voltage of the high threshold voltage device 142 in the read only memory area 122. Finally, the third photoresist layer 136 is removed. The third photoresist layer 136 can either cover the buried drain 114 or expose the buried drain 114.

Since there are the high threshold voltage device 142 and the low threshold voltage device 144 in the read only memory area 122, they can represent 0&1 or 1&0 respectively in order to achieve the objective of information or data storage when a chip is operating. The ROM code implantation process can be performed after the formation of the word lines 126 and the gate 130 of the periphery transistor 128, and before completing the periphery transistors 128; after removing the ONO dielectric layer 112, and before the forming of the gate oxide layer 120 by thermal oxidation; or after depositing the polysilicon layer 124, and before etching the polysilicon layer 124.

After completing the ROM code implantation, the manufacturing of the inter-metal dielectric(ILD, not shown), the metal layer(not shown), the contact hole(not shown) and the contact plug(not shown) on the system on chip 100 are performed to complete all of the manufacturing process of the system on chip 100. The system on chip 100 not only comprises some periphery transistors 128 in the periphery circuits, but also comprises read only memory and nitride read only memory 146.

The method of forming the system on chip in the present invention is to utilize the nitride read only memory and the added ion implantation process to simultaneously form the read only memory and the nitride read only memory on the same chip. Therefore not only can the time and manpower exhausted by electrical writing, which leads to the unfeasibility of mass production, generally required after completing the non-volatile memory be avoided, but also the cost of the nitride read only memory is as low as the mask read only memory because of the simple manufacturing process, and its function is as powerful as the flash ROM. The method of forming the system on chip comprising read only memory and nitride read only memory by utilizing nitride read only memory will decrease cost greatly and simplify the manufacturing process obviously when compared with the prior art method.

Compared to the prior art method of forming the flash ROM chip comprising read only memory, the present invention utilizes the nitride read only memory and added ion implantation process to simultaneously form the read only memory and the nitride read only memory on the same chip. Therefore not only can the time and manpower exhausted by electrical writing, which leads to the unfeasibility of mass production, generally required after completing the non-volatile memory be avoided, but also the cost can be decreased greatly and the manufacturing process can be simplified obviously, making the present invention competitive with the flash ROM in functionality.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming a system on chip (SOC), the method utilizing nitride read only memory (NROM) to establish read only memory (ROM) and non-volatile memory, a substrate of the system on chip comprising a memory area and a periphery area, the memory area further comprising a non-volatile memory area and a read only memory area, the read only memory area further comprising at least a low threshold voltage (low Vₜₕ) device area and a high threshold voltage (high Vₜₕ) device area, the method comprising:
forming a plurality of field oxide layers on the surface of the substrate so as to form an isolator of each device in the periphery area, the non-volatile memory area, and the read only memory area, respectively, and to define the active area of each device;
forming an ONO dielectric layer on the surface of the substrate, the ONO dielectric layer comprising a bottom oxide layer, a silicon nitride layer, and a top oxide layer;
forming a first photoresist layer on the surface of the ONO dielectric layer, and performing a first lithography process so as to define sites for a plurality of bit lines;
performing a first etching process, the first etching process utilizing the first photoresist layer as a mask so as to remove the top oxide layer and the silicon nitride layer and part of the bottom oxide layer not covered by the first photoresist layer;
performing a first ion implantation process so as to form a plurality of N-type doping areas, and each of the buried bit lines in the memory area; removing the first photoresist layer;
performing a thermal oxidation process so as to form a buried drain oxide layer atop the surface of each buried bit line;
forming first a polysilicon layer and then a second photoresist layer on the surface of the substrate so as to define sites of a plurality of word lines in the memory area and a plurality of gates in the periphery area in the second photoresist layer by utilizing a second lithography process;
performing a second etching process to simultaneously remove the polysilicon layer not covered by the second photoresist layer and form each of the word lines in the memory area and each gate of the periphery transistor in the periphery area, so as to form at least one NROM in the non-volatile memory area, a low threshold voltage(low Vₜₕ) device in the low threshold voltage device area of the read only memory area, and a high threshold voltage(high Vₜₕ) device in the high threshold voltage device area in the read only memory area; and
removing the second photoresist layer.

2. The method of claim 1 wherein the substrate is a silicon substrate.

3. The method of claim 1 wherein the bottom oxide layer is formed by utilizing a low temperature oxidation process with a temperature ranging from 750° C. to 1000° C. and a thickness ranging from 20 Å (angstroms) to 150 Å.

4. The method of claim 1 wherein the silicon nitride layer is formed by utilizing a low pressure vapor deposition(LPCVD) process, for use as a floating gate of the NROM, and has a thickness ranging from 50 Å (angstroms) to 300 Å.

5. The method of claim 1 wherein the top oxide layer is formed by utilizing a wet oxidation process with a thickness ranging from 50 Å (angstroms) to 200 Å.

6. The method of claim 1 wherein the method further comprises an ion implantation process for adjusting a threshold voltage of each periphery transistor.

7. The method of claim 6 wherein the ion implantation process is performed before forming the ONO dielectric layer.

8. The method of claim 6 wherein the ion implantation process is performed after forming the ONO dielectric layer.

9. The method of claim 1 wherein the method further comprises a first angled ion implantation process and a second angled ion implantation process so as to form a P-type pocket doping area at two relative sides of each bit line.

10. The method of claim 9 wherein the first angled ion implantation process and a second angled ion implantation process are performed before the first ion implantation process.

11. The method of claim 9 wherein the first angled ion implantation process and a second angled ion implantation process are performed after the first ion implantation process.

12. The method of claim 1 wherein the method further comprises a third etching process so as to remove the ONO dielectric layer on the active area in the periphery area.

13. The method of claim 12 wherein the thermal oxidation process simultaneously forms at least a silicon oxide layer on the surface of the active area in the periphery area for use as the gate oxide layer of each periphery transistor.

14. The method of claim 13 wherein after removing the ONO dielectric layer and before forming the gate oxide layer the method further comprises:
performing a third lithography process so as to form a patterned third photoresist layer, the third photoresist layer covering the low threshold voltage (low Vₜₕ)device in the read only memory area, the nitride read only memory area and the periphery area;
performing an ion implantation process for threshold voltage adjustment, implanting P-type dopant into the high threshold voltage device to adjust the threshold voltage of the high threshold voltage device and complete a ROM code process; and
removing the third photoresist layer.

15. The method of claim 14 wherein the third photoresist layer covers each bit line.

16. The method of claim 1 wherein after removing the second photoresist layer the method further comprising:
performing a fourth lithography process so as to form a patterned fourth photoresist layer, the fourth photoresist layer covering the low threshold voltage(low Vₜₕ)device in the read only memory area, the nitride read only memory area and the periphery area;
performing an ion implantation process for threshold voltage adjustment, implanting P type dopant into the high threshold voltage device to adjust the threshold voltage of the high threshold voltage device and complete the ROM code process; and
removing the fourth photoresist layer.

17. The method of claim 1 wherein after forming the polysilicon layer and before etching the polysilicon layer the method further comprising:
performing a fifth lithography process so as to form a patterned fifth photoresist layer, the fifth photoresist layer covering the low threshold voltage (low Vₜₕ)device in the read only memory area, the nitride read only memory area and the periphery area;
performing an ion implantation process for threshold voltage adjustment, implanting P type dopant into the high threshold voltage device to adjust the threshold voltage of the high threshold voltage device and complete the ROM code process; and
removing the fifth photoresist layer.

18. The method of claim 1 wherein a polysilicide layer is formed on the surface of the polysilicon layer.

19. The method of claim 1 wherein the high threshold voltage device and the low threshold voltage device are for presenting 0&1 or 1&0 respectively so as to store a specific information or data.

20. The method of claim 1 wherein the read only memory area is a mask read only memory(mask ROM, MROM) area.
